(19) United States
(12) Patent Application Publication
(10) Pub. No.: US 2016/0107253 A1
(43) Pub. Date: Apr. 21, 2016

(54) REEL-TO-REEL MANUFACTURING PLANT FOR INTERLINKED CONTINUOUS AND DISCONTINUOUS PROCESSING STEPS

(71) Applicant: Rehm Thermal Systems GmbH, Blaubeuren-Seissen (DE)

(72) Inventors: Jochen KUHN, Blaubeuren-Seissen (DE); Helmut Oettl, Blaubeuren-Seisson (DE)

(21) Appl. No.: 14/881,382

(22) Filed: Oct. 13, 2015

(30) Foreign Application Priority Data
Oct. 17, 2014 (EP) 14189335.4

(51) Int. Cl. B23K 3/06; B23K 1/00; H05K 3/22; B23K 3/04

(52) U.S. Cl. CPC B23K 3/06; B23K 3/04; B23K 1/0016; H05K 3/22; H05K 2203/043; H05K 2203/163

(57) ABSTRACT

A continuous manufacturing plant (100) for processing a strip-like substrate (101). A first drive moves the substrate in a direction of transport (x) and passes through process zones (110, 120, 130), so that different regions of the substrate are processed simultaneously. The process zones comprise a first process zone (110, 120) for a discontinuous process and a second process zone (130) for a continuous process. The continuous process is a reflow soldering process. The reflow soldering process (130) comprises a source of heat (W) and a second drive for moving the source of heat relative to the first process zone along the substrate. The second drive moves the source of heat (W) relative to the first process zone (110, 120) along the substrate (101) opposed to the direction of transport (X) of the substrate (101), even if the first drive is standing still.

### FIELD OF THE INVENTION

The present invention relates to a continuous manufacturing plant, in particular a reel-to-reel continuous manufacturing plant, for processing a strip-like substrate. The continuous manufacturing plant comprises a first drive apparatus for moving the strip-like substrate in a direction of transport, and at least two process zones which the strip-like substrate passes through so that different regions of the strip-like substrate may be processed simultaneously, the at least two process zones comprising: a first process zone for a discontinuous process and a second process zone for a continuous process, the continuous process being carried out with a reflow soldering process arrangement. The reflow soldering process arrangement comprises at least one source of heat. The present invention also relates to a method for the continuous manufacture of a product on a strip-like substrate using this device.

### BACKGROUND OF THE INVENTION

Such a device is known, for example, from the European patent application intended to be granted as a patent and bearing the publication No. EP 2 160 263 with the title “REFLOW SOLDERING SYSTEM WITH A TEMPERATURE PROFILE WHICH CAN BE ADAPTED TO EXTERNAL TRANSPORT SPEEDS”.

Systems for the reel-to-reel continuous manufacture (reel-2-reel) are rather rarely employed in the reflow soldering of electronic assemblies on flexible foils. The main obstacle is the connection of the reflow process with the other preceding process steps, for example the printing of a paste for the strip conductors and the application of electric and electronic components. While the printing process for applying the paste and the application of components, for example, are carried out sequentially (discontinuously), i.e. the strip is standing still during the performance of these processes, the reflow process must be carried out continuously due to thermal requirements.

For establishing the electrical connections between the components, the strip-like substrate is initially printed with a solder paste and subsequently equipped with the components. Upon the application of the components, the strip will start to move and the equipped part of the strip-like endless substrate enters the system to remelt the solder paste. In this context, the remelting operation is to be carried out in a controlled manner which depends, among other things, on the properties of the solder paste, the components, the application density etc. For example, with components of very different sizes, the various durations of the heating times must be taken into consideration for remelting the solder paste and thus ensuring the desired quality of the connection in view of the electric, thermal and mechanical properties. Therefore, the soldering process in the system normally follows a specified sequence to thus generate a desired temperature profile on the substrate, so that on the one hand, a reliable liquefaction of the solder paste takes place within a desired period, but on the other hand, no overheating of sensitive components occurs. An interruption of the transport process therefore severely disturbs the heating process and leads to non-reproducible product results.

In the publication “Rolle-zu-Rolle-Fertigung von MID-basierten Mikrosystemen” by Dr. Hans Bell, Michael Gempp and Stephan Schulz, published in PLUS 7/2014, pages 1544 et seq., the problem of the interlinked continuous and discontinuous process steps is solved by a carrier strip with integrated product supports. Individual product supports may be released from the carrier strip to subject them, for example, to a continuous tempering process. Upon the performance of the continuous process, the product support is integrated again into the endless strip. For this solution, a great amount of apparatuses is required since separate transport devices must be provided for the discontinuous and continuous processes and interlocked conveying belts must be produced in complex processes, for example in a continuous injection molding process. Furthermore, devices for releasing and integrating again the interlocked product supports in the interlocked conveying belt must be provided.

EP 2 160 263 also addresses the problem of difficulties in case a substrate is guided from one processing station to the next one, as is the case, for example, when endless flexible substrates are being processed since the determining line cycle then must be harmonized with the thermodynamic requirements of the remelting soldering operation. It is described therein that an “endless” substrate includes equal sections arranged in line, for example circuits or printed circuit boards, also referred to as “images”, where in most cases only a few millimeters of substrate are present between the individual circuits, for example to facilitate the later separation process. To permit a continuous transport operation in the reflow soldering system, a “buffer” in the form of a loose loop is provided upstream of the system to take into account the different transport speeds and methods of the individual processing systems, i.e. the application device, the printing device, and the reflow process system. To be able to adjust heating profiles in a flexible manner, in EP 2 160 263, a source of heat in the form of a segmented heat conduction surface is provided. Individual segments can be exchanged to flexibly adjust a temperature profile. For this, the individual segments are provided with drive units by which the heating plate segments may be shifted perpendicularly to the direction of transport or in parallel to the direction of transport. If, for example, a heating segment is replaced by a cooling segment, the heating segment is pushed out of the heating area perpendicularly to the direction of transport of the substrate strip, and a cooling segment is pushed in. If smaller or larger segments, as compared to the segment to be replaced, are to be inserted into the heating area, the adjacent segments must be shifted along the direction of transport to provide a preferably uninterrupted heating/cooling area. While in EP 2 160 263, individual heating elements are movable relative to the strip-like substrate, a continuous soldering operation is only possible if the strip-like substrate moves in accordance with the temperature profile of the heating area. The adaption of the strip motion between the upstream discontinuous printing and application process and the downstream continuous soldering process is exclusively effected via the strip buffer in the form of a strip loop. This, however, is difficult to realize technically as due to the strong bends of the strip-like substrate, problems with the adherence of the solder and the electric components occur.

It is therefore an object of the present invention to provide a continuous manufacturing plant which interlinks continuous thermal processing operations and discontinuous processing operations, such as for example application procedures, in an inexpensive manner. It is furthermore an object of the present invention to provide a method for the continuous manufacture of electric or electronic products by which discontinuous processing steps and continuous processing steps may be interlinked in an inexpensive manner.

### SUMMARY OF THE INVENTION

This object is achieved by a continuous manufacturing plant according to an embodiment of the invention.

In particular, the object is achieved by a continuous manufacturing plant of the type mentioned in the beginning which is characterized by a second drive apparatus for moving the source of heat relative to the first process zone along the strip-like substrate which is configured to move the source of heat relative to the first process zone along the strip-like substrate against the direction of transport of the strip-like substrate even if the first drive apparatus is standing still.

The continuous manufacturing plant according to the invention has the effect that the temperature profile required for a soldering process is generated by the movement of the source of heat against the running direction of the strip. This involves the mechanism for moving the source of heat being designed such that the path is long enough to generate corresponding temperature profiles.

In one embodiment thereof, the continuous manufacturing plant furthermore comprises a control device which is configured to control the second drive apparatus such that the source of heat is moved in such a way that a predetermined temperature profile T(t) required for the soldering process is obtained over a predetermined area of the strip-like substrate.

The temperature profiles are generated by the source of heat being moved against the direction of transport of the strip. Thereby, a transit principle may be simulated, so that a continuous tempering process may be carried out for a product on the strip-like substrate even if the strip-like substrate is standing still to apply solder at another location of the strip-like substrate and apply electric components on the strip conductors. This means that the continuous thermal process may be carried out independent of differently clocked upstream or downstream processing steps.

The heat treatment during the movement of the source of heat opposed to the direction of transport of the strip furthermore permits to achieve a better thermal separation of following images which enter the reflow soldering system. If the source of heat is switched off when it is returned to its original position, the temperature-treated region may cool down in a controlled manner, and heat transfer to the following products becomes less. This is of particular advantage if following images require a different temperature profile and temperature influences of preceding products would disturb the temperature profile.

Furthermore, by the heat treatment during the movement of the source of heat opposed to the direction of transport of the strip, it is possible to process any product lengths, which are also referred to as image lengths, on the strip. The maximum image length is only determined by the travel way of the heat field. The strip speed must be adapted to the image length. The strip speed, however, may also influence the temperature profile. To be able to utilize the manufacturing plant as flexibly and precisely as possible, in one embodiment, the control device is configured to control the transport speed of the strip-like substrate depending on the product length and/or the predetermined temperature profile.

When the strip is standing still, the temperature profile is determined by the temperature distribution of the heat field and by the speed by which the source of heat is moved.

In the simplest case, a desired temperature profile may be obtained, for example, with a point source of heat whose thermal energy is focused on a point or a line on the substrate. This would correspond to a strictly confined linear heat field. In this case, the temperature profile is determined by the speed and the intensity of radiation of the source of heat. The shape of the heat field is of minor importance.

In one embodiment, however, the source of heat may also be segmented, so that heat fields of any shape, or also a plurality of spatially separated heat fields with predetermined temperature distributions may be generated. More extended heat fields may possibly reduce the processing times and provide more uniform temperature distributions.

For example, in one embodiment, the control device may be configured to individually control the intensity of the at least one source of heat or the individual segments of the source of heat depending on the predetermined temperature profile, such that a heat field with a given temperature distribution is formed. Depending on the product sizes and component heights, different temperature profiles are required to carry out an optimal soldering process. To increase the flexibility of the reflow soldering process, this embodiment permits a customized design of the heat fields, for example by activating individual segments of the source of heat.

In another embodiment, at the inlet and/or outlet of the reflow soldering process arrangement, additional sources of heat are arranged stationarily or movably together with the strip-like substrate. This has the advantage that an undefined heat absorption by the strip material is reduced since the strip material is maintained at a defined temperature.

In another embodiment, the continuous manufacturing plant furthermore comprises at least one thermometer by which the control device may control the movement of the strip-like substrate and/or the movement of the at least one source of heat and/or the shape of the heat field of the source of heat, for example by controlling the intensity of the segments of the source of heat, to obtain a desired heat profile. In this context, the thermometer may comprise a pyrometer, a thermo sensor, a thermal imaging camera, a thermoelement or combinations thereof which may be arranged at a selected point or at several selected points in the process region.

Thereby, the temperature profiles may be better adjusted in a control loop and reproducible soldering results may be obtained.

As sources of heat, infrared radiators may comprise, for example as batwing radiators or focused radiators, heated thermal conductors, such as heating plates or cooling plates, convective heat sources, such as hot air blowers, condensation heat sources or laser heat sources, or a combination thereof. In reel-to-reel manufacture, convective heat sources have proved to be advantageous, so that well-known plant technology may be inexpensively used. In the claimed system with a source of heat that is moved in the opposite direction, an infrared radiator, in particular a focused infrared beam, is a simple and advantageous possibility of generating a desired heat profile. The infrared radiators may also be easily realized as array so that relatively complicated heat fields may also be generated. As semiconductor laser and light-emitting diode (LED) technologies progress, light-emitting diodes (LED) and semiconductor lasers, in particular vertically emitting semiconductor lasers (VCSEL), are employed as source of infrared radiation. For selective cooling, cooled or heated heat conductors, for example hot plates/cold plates, may also be used.

The above-mentioned object is also achieved by a method for the continuous manufacture of a product on a strip-like substrate that is moving through a plurality of process zones in a direction of transport, where different regions of the strip-like substrate are simultaneously processed in different process zones and where in a second process zone, a continuous heat treatment process is performed, wherein a source of heat is moving relative to the strip-like substrate and in a first process zone a discontinuous process is performed, wherein a process tool is standing still relative to the strip-like substrate. The method is characterized by a first procedure step of stopping the strip-like substrate; and a second procedure step of moving the source of heat in the second process zone in a direction opposed to the direction of transport of the strip-like substrate and simultaneously processing said substrate in the first process zone.

As already mentioned above, this method has the advantage that the discontinuous process of printing and equipping the strip-like substrate, i.e. the working processes when the strip is standing still, may be interlinked with the continuous thermal process (i.e. the process that requires a movement of the strip relative to the process zone). This means that the continuous process may be performed independent of the cycles of the discontinuous processes.

In one embodiment of the method, the second procedure step furthermore comprises switching on and controlling the source of heat to generate a predetermined temperature profile, the step of controlling the source of heat comprising at least one of: controlling the intensity of the source of heat or of segments of a segmented source of heat to generate a heat field with predetermined temperature distribution; and controlling the movement of the source of heat. Thereby, any desired temperature profiles may be generated and the plant may be flexibly utilized for different images and image sizes.

In another embodiment, the second procedure step furthermore comprises: detecting the temperature at least at one point of the strip-like substrate in the second process zone; measuring a temperature profile of the strip-like substrate in the second process zone; comparing the measured temperature profile with the predetermined temperature profile; and controlling the source of heat to minimize a difference between the predetermined and the measured temperature profile. Thereby, one obtains reproducible results for the soldering process.

In another embodiment, the method furthermore comprises a third procedure step of starting the transport motion of the strip-like substrate; and a fourth procedure step of reversing the moving direction of the source of heat. The third and fourth procedure steps are accomplished when the discontinuous processes, such as applying the solder paste and the components, are terminated and the next section of the strip-like substrate is transported to the process zones. The third and fourth procedure steps may be carried out such that the thermal process is continuously continued. However, it is also advantageous to switch off the source of heat as long as it is moving in the same direction as the direction of transport of the strip-like substrate to permit a controlled cooling down of the temperature-controlled substrate section and to reduce the heat transfer along the substrate strip.

If the source of heat is not switched off, the movement of the source of heat may be controlled such that a relative motion with a constant speed between the sources of heat and the substrate is always given, even if the strip-like substrate is at rest relative to the second process zone. In this case, a continuous, i.e. uninterrupted heat treatment of the substrate material is accomplished, no matter if the strip-like substrate is moving or standing still.

It should be noted that the described procedure steps (first procedure step, second procedure step, third procedure step, fourth procedure step) are carried out one after the other while the processes within one procedure step may take place simultaneously.

### BRIEF DESCRIPTION OF THE DRAWINGS

Below, embodiments, developments, advantages and possible applications of the invention will be illustrated in more detail with reference to the enclosed figures. Here, all described and/or illustrated features by themselves or in any combination are basically the subject matter of the invention, independent of their summary in the claims or their references. Moreover, the contents of the claims are made part of the description. In the figures:

FIG. 1 shows an embodiment of the continuous manufacturing plant according to the present invention;

FIG. 2 shows a temperature distribution of a focused infrared heat source;

FIG. 3 shows a temperature profile in a reflow soldering process;

FIG. 4 shows an example of a heat field in a segmented source of heat; and

FIG. 5 shows an example of spatially separated heat fields that may be generated by stringing together a plurality of segmented sources of heat.

### DETAILED DESCRIPTION OF EMBODIMENTS

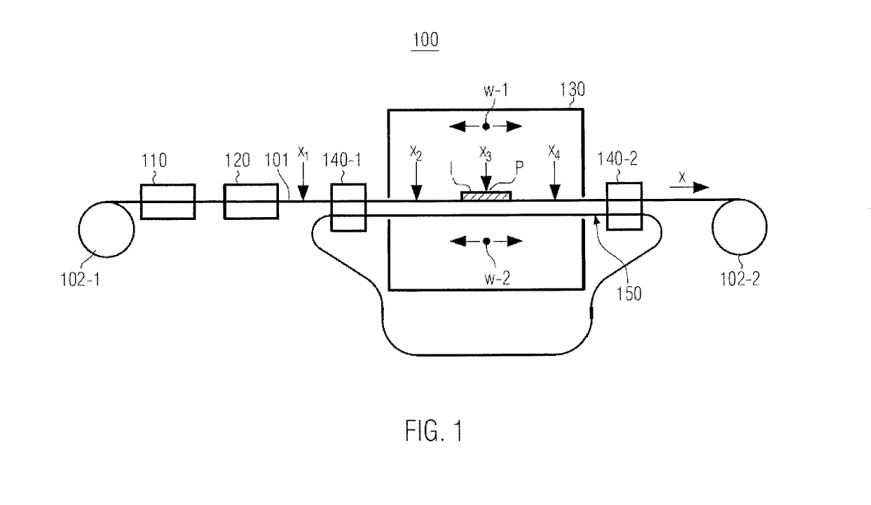

FIG. 1 shows an embodiment of a continuous manufacturing plant for reel-to-reel manufacture of electronic products by processing a strip-like substrate 101. The strip-like substrate 101 consists of a flexible material, for example plastic, textile fabric or metal, for example copper, which is reeled off from a reel 102-1 at the inlet side of the plant 100, processed in the plant 100 and reeled on again on a reel 102-2 at the outlet side of the plant 100. The strip-like substrate 101 passes through the system 100 and is processed in the process zones 110, 120 and 130. The process zone 110 may be, for example, a printing station for printing the solder paste onto the strip 101, station 120 may be an application station in which corresponding components are automatically applied, and station 130 represents a reflow soldering system. The direction of transport of the strip-like substrate 101 is designated with X (see arrow on the right in FIG. 1). In the arrangement represented in FIG. 1, the reflow soldering system 130 is accommodated in a chamber with an inlet and an outlet opening through which the strip-like substrate 101 is passed. In the chamber of the reflow soldering system, a source of heat is shown which is arranged symmetrically above and underneath the strip-like substrate 101 (reference numerals W-1 and W-2). To adjust the temperature profile more precisely, the source of heat W-1 and W-2 are respectively arranged above and underneath the strip-like substrate 101. The arrows in FIG. 1 right and left of the sources of heat W-1 and W-2 indicate that the sources of heat W-1 and W-2 may be moved synchronously with respect to each other along the strip-like substrate 101. The two-piece design of the source of heat W-1 and W-2, however, is not compulsory as even with only one source of heat W-1 over the strip-like substrate, temperature profiles may be realized. A support 150 for the strip-like substrate 101 which consists of a heat-resistant material with low sliding friction values, for example a heat-resistant and low friction material sold under the trademark Teflon, serves as backing for the strip-like substrate, so that deformations of the strip-like substrate 101, for example undulations or a lateral bend of the strip due to the action of heat in the reflow process arrangement 130, are smoothed. To secure the undefined heat absorption by the strip material, in addition one source of heat 140-1 is arranged at the inlet and one source of heat 140-2 at the outlet of the system and keep the strip material 101 at a defined temperature. The sources of heat 140-1 and 140-2 may be stationary or also be moved along. FIG. 1 also shows a product I (image) underneath the source of heat W-1.

Below, the method will be described by which a product I (image) is processed on its way from the dispenser reel 102-1 through the process zones 110, 120 and 130 to the receiving reel 102-2. Initially, the product is not in a precisely specified region on the strip-like substrate 101 which is reeled off from the dispenser reel 102-1. A non-depicted control device causes a non-depicted drive apparatus to move the strip-like substrate 101 such that the product region on the strip-like substrate 101 is moved into a first process zone 110. When the product region is located in the first process zone 110, the control unit causes the first drive apparatus to stop the strip-like substrate. In the first process region 110, for example, the product region is printed with a solder paste which represents strip conductors, for example. Upon printing of the substrate material in the first process zone 110, the strip-like substrate 101 is caused to move by the first drive apparatus upon instructions of the control device to transport the printed region of the strip into the second process zone 120. There, the strip-like substrate 101 is stopped again and the printed part of the substrate is equipped with electronic components.

Subsequently, the strip-like substrate 101 is moved again, so that the blank image I is transported through the reflow soldering system 130. In the process, the image I or the blank image (i.e. the not yet finished product) passes points X1, X2, X3, and X4 of a coordinate system that is stationary with respect to the continuous manufacturing plant. In a continuous movement of the strip-like substrate 101, for example a point P on the image I is at place X1 at a point in time t1, at place X2 at a point in time t2, at place X3 at a point in time t3, and at place X4 at a point in time t4. The blank image is moved by the control device, for example to point X3. At this time, no application or printing processes take place in the upstream strip region. The blank image I is moved, for example, to point X3, while a just printed strip section is transported from the first process region 110 into the second process region 120.

It should be noted that FIG. 1 is just a schematic representation of the plant and does not show a correct scale of the distances between the individual stations and the sizes of the stations themselves. FIG. 1 only serves to illustrate the structural composition of the plant and illustrates the operations of the plant.

At point X3, the blank image I is stopped so that in the process zones 110 and 120, the printing and application operations may be started on the strip-like substrate 101. At this point in time, the sources of heat W-1 and W-2 are located, for example, at point X4. Just after the strip-like substrate has been stopped, the control device causes the source of heat W-1 to move in a direction opposed to the direction of transport of the strip and to move over the blank image I. By controlling the speed of the source of heat W-1 and W-2, the temperature and the temperature gradient, i.e. how quickly the temperature changes at a certain point on the substrate, may be adjusted to achieve a controlled remelting of the solder and cooling down of the solder without damaging the electric components.

FIG. 1 shows a chamber 130 that is relatively large as compared to the image I and in which only one single image I is being processed. This, however, is only a simplified schematic representation of the plant and the operation and intends to also show the flexibility of the plant. For example, in the chamber of the reflow soldering process arrangement 130, one very large image I or a plurality of small images may be processed, so that the complete moving area of the source of heat W-1 and W-2 from point X4 to point X2 may be utilized.

When all images in the chamber of the reflow soldering process arrangement 130 have been heat treated, the source of heat W-1 and W-2 is at the left end of the chamber, for example at place X2, and the control device stops the movement of the source of heat W-1 and W-2. After that, the control device starts again the movement of the strip-like substrate, so that the image I is moved out of the reflow soldering process arrangement 130 and moves towards the receiving reel 102-2 where the products are finally reeled on. Simultaneously with the start of the movement of the strip-like substrate 101, the control device causes the source of heat W-1 and W-2 to move with the strip 101 again to the other end of the chamber of the reflow soldering process arrangement 130. During this movement of the source of heat in the same direction as the direction of transport of the strip-like substrate 101, the control device switches off the source of heat W-1 and W-2, so that during this time, no heat treatment takes place. This has the advantage that the images in the chamber of the reflow soldering process arrangement 130 may cool down in a controlled manner and one obtains a better thermal separation to the following images which are not yet heat treated. For example, subsequent images may represent other products with other electric components requiring another heat profile. By returning the source of heat W-1 and W-2 to the opposite side of the chamber of the reflow soldering process arrangement 130 in a switched-off state, the influence of the heat profile on subsequent images, which optionally require a different heat profile, is reduced. Furthermore, during the movement of the source of heat in a switched-off state, defined regions of the strip-like substrate may be selectively cooled down without influencing adjacent regions, so that reproducible solder results are achieved.

With invariable products, however, it is also possible to leave the source of heat W-1 and W-2 switched on when they are being returned. In this case, the rate of motion of the source of heat W-1 and W-2 is lower than the transport speed of the strip-like substrate. The speed difference is here selected such that a continuous tempering process takes place in the reflow soldering process arrangement 130 with a constant temperature profile, so that there is a continuous relative motion between the source of heat and the strip-like substrate 101 with a constant speed although the strip motion is clocked and the source of heat constantly reciprocates in the chamber of the reflow soldering process arrangement 130.

In FIG. 1, the source of heat is, for the sake of simplicity, shown as a point source of heat or a linear source of heat over the complete width of the substrate. This may be achieved, for example, via a resistance wire which is guided across the strip transversely to the running direction or an infrared laser diode with an optic that focuses the emitted infrared radiation linearly across the strip onto the surface of the strip.

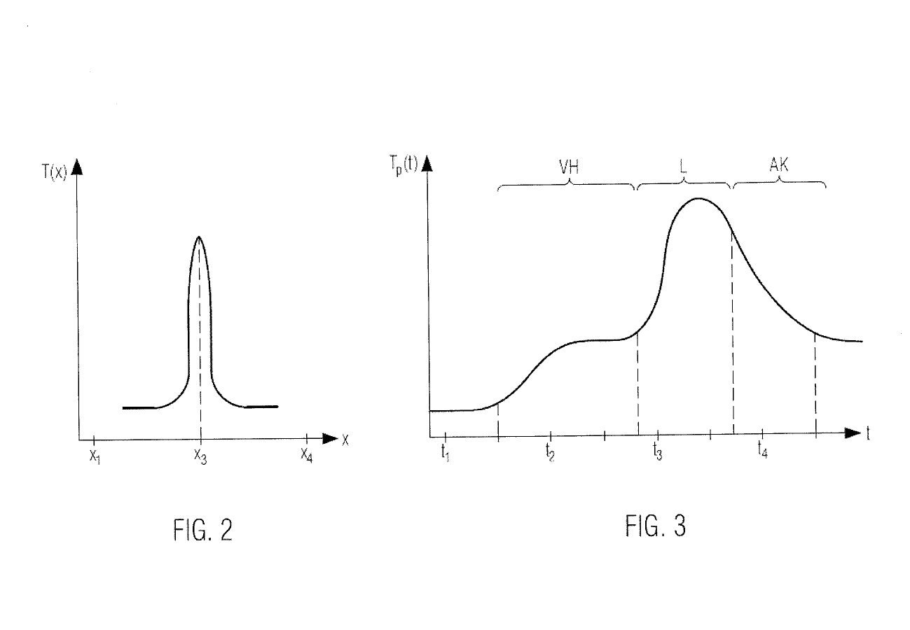

FIG. 2 shows a heat field which may be achieved with such a point source of heat. FIG. 2 shows in particular a temperature distribution for a heat field of a point source of heat which is, for example, focused on point P on the image I in FIG. 1. Due to the focused thermal energy, a narrow temperature peak is formed which is guided over the image. Depending on the speed at which the source of heat is guided over the image, the surface of the image heats up to a greater or lesser extent. For example, the speed is selected such that the temperature at the solder to be remelted is about 230° C. Depending on the thermal capacity and thermal conductivity of the substrate, the solder and the electronic components, the speed at which the source of heat must be guided over the image to achieve this temperature for remelting the solder may be varied.

In case of a non-focused infrared radiation, the peak shown in FIG. 2 would be wider. With a wider peak, for example only lower temperature increase rates may be achieved at a certain point in an image than with a focused infrared beam. The focused infrared beam permits a more precise control of the temperature profile, but it involves the risk of the temperature on the image increasing at a certain point too quickly, so that the image damages the product due to mechanical stress between the materials that expand at different speeds or rates.

FIG. 3 shows a typical temperature profile as it is required in a reflow soldering process. The soldering profile shows a variation of temperature over time at a certain point on an image. In contrast, the temperature distribution in FIG. 2 shows a spatial temperature distribution on the image, i.e. independent of time.

In FIG. 3, the temperature is represented at point P on the image I of FIG. 1. Point P goes, when the plant is in operation, from point X1 via points X2 and X3 to point X4. At the point in time t1, point P is located at point X1 of the manufacturing plant. The temperature prevailing there corresponds to ambient temperature outside the reflow soldering process arrangement 130. On the way from point X1 to point X2, point P on the image I passes a preheating region 140-1 (see FIG. 1) where the substrate is heated to about 100° C. This corresponds to the region VH (preheating) in FIG. 3. At the point in time t3, point P is approximately at point X3 within the reflow soldering process arrangement 130 and the strip 101 is standing still. Simultaneously, the source of heat W-1 and W-2 has moved across point P, so that a relatively steep increase in temperature at point P is indicated. In this region of increased temperatures, the soldering process takes place by the solder being remelted and connecting with the substrate and the terminals of the components. This solder region is designated with L (soldering) in FIG. 3. When the source of heat has passed point P, point P will start to cool down the further the source of heat moves away from point P until the source of heat is switched off. Then, the strip 101 movement is switched on again and point P moves towards point X4 which it reaches at point in time t4. The downstream source of heat 140-2 at the outlet of the reflow soldering process arrangement 130 takes care that no uncontrolled heat losses occur by heat conduction via the strip 101, so that the temperature at point X4, i.e. at point in time t4, is, for example, about 100° C.

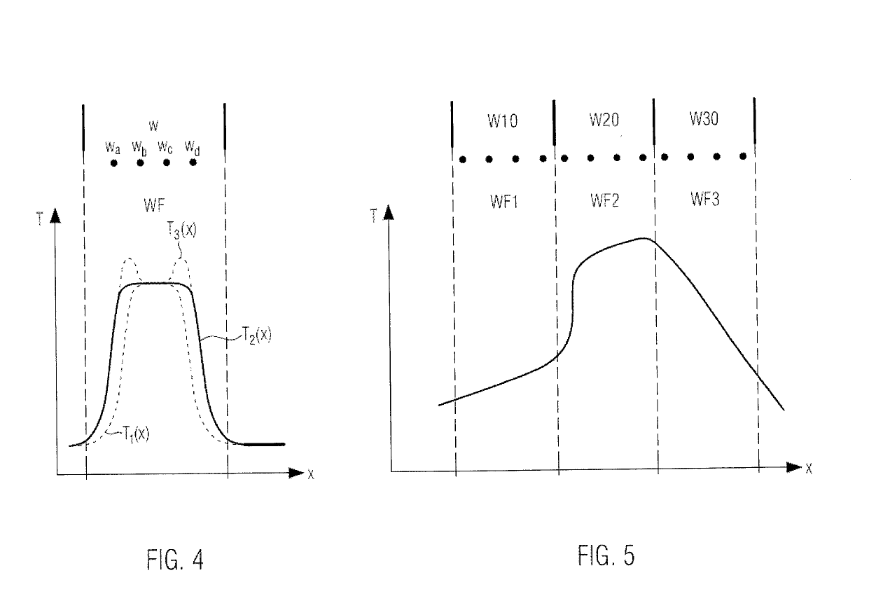

As was already mentioned above, a required temperature profile T(t) depends on the structure of the product and its parameters, for example thermal capacity and thermal conductivity of the substrate, the solder and the components, so that optionally, the required temperature profile is difficult to reach with a point source of heat. In this case, the source of heat may be embodied in the form of a screened heat matrix consisting of one or several individually controllable fields. FIG. 4 shows a source of heat W with four segments Wa, Wb, Wc, and Wd by which a more complex heat field WF may be realized. FIG. 5 shows an array of three adjacent screened sources of heat W10, W20, and W30 which may generate three different spatial separated heat fields WF1, WF2, and WF3.

FIG. 4 shows three different heat fields WF which may be realized, by way of example, with the screened source of heat W if the individual segments Wa, Wb, Wc, and Wd can be adjusted individually. The temperature distribution T₁(X) shows a case where the intensity of the external sources of heat Wa and Wd are adjusted to be smaller than the intensity of the central segments Wb and Wc. T₂(X) shows a heat field WF where all segments contribute the same intensity. The temperature distribution T₃(X) of the heat field WF shows a case where the external segments Wa and Wd have a higher intensity in the heat field than the central segments Wb and Wc. The temperature distribution T₁(X) leads to flatter temperature profiles, while the other extreme, the temperature distribution T₃(X), may be used for temperature profiles requiring quicker local heating.

FIG. 5 shows a source of heat in which the preheating region and the cooling region are already integrated in the source of heat and are moved over the image together with the solder region. The heat field WF1 serves, for example, for preheating, the heat field WF2 serves for soldering, and the heat field WF3 serves for cooling.

Such complex heat fields do not necessarily have to be realized with sources of heat according to the same structural principle but may also integrate different technologies. For example, the heat field WF1 may be realized with an infrared radiator, the heat field WF2 with a convective source of heat, and the heat field WF3 with a cold plate. Any technologies may be combined, for example infrared radiators, focused infrared radiators, heated heat conductors, for example hot plates or cold plates, a convective source of heat, a condensation source of heat, a source of heat on the basis of infrared lasers, infrared semiconductor lasers, VSCEL apparatuses (Vertical-Cavity Surface-Emitting Lasers), or infrared light-emitting diodes.

To increase the reproducibility of the soldering process, different closed-loop control operations may be used to adjust the temperature profiles in a better reproducible and more precise manner. For example, with temperature sensors in the reflow soldering system, a temperature profile or a temperature distribution in the system may be measured, and based on these values, process parameters may be adjusted such that the temperature profile required for the soldering process is adjusted as precisely and reproducibly as possible. For example, the temperature profile may be modified by changing the transport speed of the strip-like substrate, the rate of motion of the source of heat and by individually adjusting individual segments of the segmented source of heat or by adjusting the heat fields in a heat field array (see FIG. 5). For measuring temperature, pyrometers, thermo sensors, thermoelements, a thermal imaging camera or combinations thereof may be used. A plurality of thermometers may be used which are distributed in the reflow soldering process arrangement, or an individual sensor may be used which is carried along relative to a certain point P on an image I.

While the present invention has been described with respect to several embodiments, it will be understood that various modifications may be made without departing from the spirit or scope of the invention.

What is claimed is:

1. Continuous manufacturing plant for processing a strip-like substrate, comprising:
a first drive apparatus for moving the strip-like substrate in a direction of transport;
at least two process zones which the strip-like substrate passes through, so that different regions of the strip-like substrate may be processed simultaneously,
wherein said at least two process zones comprise:
a first process zone, and
a second process zone with a reflow soldering process arrangement, wherein the reflow soldering process arrangement comprises at least one source of heat;
a second drive apparatus for moving the source of heat relative to said first process zone along the strip-like substrate which is configured to move the source of heat relative to the first process zone along the strip-like substrate opposed to the direction of transport of the strip-like substrate even if the first drive apparatus is standing still.

2. Continuous manufacturing plant according to claim 1, furthermore comprising:
a control device which is configured to control said second drive apparatus such that the at least one source of heat is moved such that a predetermined temperature profile required for a soldering process is reached over a predetermined region of the strip-like substrate.

3. Continuous manufacturing plant according to claim 2, wherein:
said control device is configured to control a transport speed of the strip-like substrate depending on the product length and/or the predetermined temperature profile.

4. Continuous manufacturing plant according to claim 1 wherein:
the at least one source of heat is segmented, so that it may generate a heat field or a plurality of spatially separated heat fields with a predetermined temperature distribution.

5. Continuous manufacturing plant according to claim 2, wherein:
said control device is configured to control the intensity of the at least one source of heat depending on the predetermined temperature profile such that a heat field with a predetermined temperature distribution is formed.

6. Continuous manufacturing plant according to claim 1, wherein:
at an inlet and/or outlet of the second process zone, additional sources of heat are arranged stationarily or movably together with the strip-like substrate.

7. Continuous manufacturing plant according to claim 2, furthermore comprising:
at least one thermometer by which said control device may control the movement of the strip-like substrate and/or the movement of the at least one source of heat and/or a shape of the heat field of the at least one source of heat to obtain the predetermined temperature profile.

8. Continuous manufacturing plant according to claim 7, wherein:
said at least one thermometer comprises a pyrometer, a thermo sensor, a thermoelement, a thermal imaging camera or combinations thereof.

9. Continuous manufacturing plant according to claim 1, wherein:
the at least one source of heat is an infrared radiator, a heated heat conductor, a convective source of heat, a condensation source of heat, a laser source of heat or a combination thereof.

10. Method for the continuous manufacture of a product on a strip-like substrate that moves through a plurality of process zones in a direction of transport, wherein different regions of the strip-like substrate are simultaneously processed in different process zones and wherein in a second process zone, a continuous heat treatment process is performed wherein a source of heat is moving relative to the strip-like substrate, and in a first process zone, a discontinuous process is performed wherein a process tool is standing still relative to the strip-like substrate, comprising the steps of:
a first procedure step of stopping the strip-like substrate; and
a second procedure step of moving the source of heat in the second process zone in a direction opposed to the direction of transport of the strip-like substrate and simultaneously processing the strip-like substrate in the first process zone.

11. Method according to claim 10, wherein:
said second procedure step further comprises:
switching on and controlling the source of heat to generate a predetermined temperature profile.

12. Method according to claim 11, wherein:
controlling the source of heat comprises at least one of:
controlling the intensity of the source of heat or of segments of a segmented source of heat to generate a heat field with a predetermined temperature distribution; and
controlling the movement of the source of heat.

13. Method according to claim 10, wherein:
said second procedure step further comprises:
detecting the temperature at least at one point of the strip-like substrate in the second process zone;
measuring a temperature profile of the strip-like substrate in the second process zone;
comparing the measured temperature profile with a predetermined temperature profile; and
controlling the source of heat to minimize a difference between the predetermined and the measured temperature profile.

14. Method according to claim 10, furthermore comprising the following procedure steps:
a third procedure step of starting the direction of transport of the strip-like substrate; and
a fourth procedure step of reversing the moving direction of the source of heat.

15. Method according to claim 14, wherein:
said fourth procedure step further comprises switching off the source of heat.

16. Method according to claim 10, furthermore comprising the following procedure steps:
a third procedure step of starting the direction of transport of the strip-like substrate;
a fourth procedure step of reversing the moving direction of the source of heat, wherein the movement of the source of heat is controlled in such a way that there always is a relative motion at a constant speed between the sources of heat and the strip-like substrate, even if the strip-like substrate is at rest relative to the second process zone.

17. A manufacturing plant for processing a strip substrate having a plurality of products being formed thereon comprising:
a first drive coupled to the strip substrate, said first drive moving the strip substrate in a direction of transport;
a first process zone in a path of the direction of transport of the strip substrate;
a second process zone in the path of the direction of transport of the strip substrate following said first process zone;
a heater positioned in the second process zone; and
a second drive coupled to said heater, said second drive moving said heater in a direction opposite to the direction of transport of the strip substrate,
whereby said heater is capable of providing a predetermined temperature distribution to one of the plurality of products in said second process zone even when said first drive is standing still.

18. A manufacturing plant for processing a strip substrate having a plurality of products being formed thereon as in claim 17 wherein:
said second process zone comprises a reflow soldering apparatus.
